(19) United States
(12) Patent Application Publication
(10) Pub. No.: US 2020/0335472 A1
(43) Pub. Date: Oct. 22, 2020

(54) Substrate Bonding Apparatus and Substrate Bonding Method

(71) Applicant: NIKON CORPORATION, Tokyo (JP)

(72) Inventors: Kazuya OKAMOTO, Tokyo (JP); Isao SUGAYA, Kawasaki-shi (JP); Naohiko KURATA, Tokyo (JP); Masashi OKADA, Sagamihara-shi (JP); Hajime MITSUISHI, Yokohama-shi (JP)

(73) Assignee: NIKON CORPORATION, Tokyo (JP)

(21) Appl. No.: 16/918,872

(22) Filed: Jul. 1, 2020

Related U.S. Application Data
(62) Division of application No. 14/497,424, filed on Sep. 26, 2014.
Application No. 14/497,424 is a continuation of application No. PCT/JP2013/001813, filed on Mar. 15, 2013.

(30) Foreign Application Priority Data
Mar. 28, 2012 (JP) 2012-074232

(51) Int. Cl. H01L 23/00; H01L 21/67; H01L 23/544; H01L 21/66; B23K 37/04; H01L 21/68

(52) U.S. Cl. CPC H01L 24/75; H01L 21/67092; H01L 23/544; H01L 24/81; B23K 2101/40; B23K 37/04; H01L 21/68; H01L 22/12; H01L 22/20

(57) ABSTRACT

A substrate bonding apparatus that bonds a first substrate and a second substrate together, comprising a joining section that joins the first substrate and second substrate together aligned to each other for stacking; a detecting section that detects an uneven state on at least one of the first substrate and second substrate prior to joining by the joining section; and a determining section that determines whether the uneven state detected by the detecting section satisfies a predetermined condition, wherein the joining section does not join the first substrate and the second substrate if it is determined by the determining section that the uneven state does not satisfy the predetermined condition.

The contents of the following Japanese patent applications are incorporated herein by reference:
2012-074232 filed in JP on Mar. 28, 2012, and
PCT/JP2013/001813 filed on Mar. 15, 2013

### BACKGROUND

### 1. Technical Field

The present invention relates to a substrate bonding apparatus and a substrate bonding method.

### 2. Related Art

There is a multilayer type semiconductor apparatus that layers a plurality of substrates to bond together (see Japanese Unexamined Patent Application Publication No. 2005-251972). When bonding, the substrates are aligned and stacked in the precision of line width of the semiconductor apparatus, to be further joined.

A portion of the substrates, however, may not adhere to each other, even if substrates are aligned in the surface direction to be joined, depending on an uneven state on substrates to be bonded.

### SUMMARY

Therefore, it is an object of an aspect of the present invention to provide a substrate bonding apparatus and a substrate bonding method which are capable of overcoming the above drawbacks accompanying the related art. The above and other objects can be achieved by combinations described in the independent claims. That is to say, a first aspect of the present invention provides a substrate bonding apparatus that bonds a first substrate and a second substrate together, comprising: a joining section that joins the first substrate and the second substrate together aligned to each other to be stacked; a detecting section that detects an uneven state on at least one of the first substrate and the second substrate prior to the joining by the joining section; a determining section that determines whether the uneven state detected by the detecting section satisfies a predetermined condition; wherein the joining section, if the uneven state is determined by the determining section not to satisfy the predetermined condition, does not join the first substrate and the second substrate.

A second aspect of the present invention provides a substrate bonding method comprising: aligning of aligning a first substrate and a second substrate together to stack them; joining of joining the first substrate and the second substrate aligned together; prior to joining, detection of detecting an uneven state on at least one of the first substrate and the second substrate; determination of determining whether the uneven state detected by the detection satisfies a predetermined condition; wherein the joining is not performed if it is determined in the determination that the uneven state does not satisfy the predetermined condition.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 is a schematic plane view of a substrate bond apparatus 100.

FIG. 2 is a perspective view of a substrate holder 150.

FIG. 3 is a perspective view of the substrate holder 150.

FIG. 4 is a schematic sectional view of a stacking section 170.

FIG. 5 is a schematic sectional view of the stacking section 170.

FIG. 6 is a schematic sectional view of a joining section.

FIG. 7 is a sectional view showing a state transition of a substrate 121.

FIG. 8 is a sectional view showing a state transition of the substrate 121.

FIG. 9 is a sectional view showing a state transition of the substrate 121.

FIG. 10 is a sectional view showing the state transition of the substrate 121.

FIG. 11 is a schematic perspective view of the substrate 121.

FIG. 12 is a block diagram showing a portion of a total control section 110.

FIG. 13 is a flow chart showing control procedures of a determining section 116.

FIG. 14 is a flow chart showing one example of detailed control procedures of the determining section 116.

FIG. 15 is a flow chart showing another example of detailed control procedures of the determining section 116.

FIG. 16 is a flow chart showing still another example of the detailed control procedures of the determining section 116.

FIG. 17 is a flow chart showing still another example of the detailed control procedures of the determining section 116.

FIG. 18 is a flow chart showing other control procedures of the determining section 116.

FIG. 19 is a flow chart showing still other control procedures of the determining section 116.

### DESCRIPTION OF EXEMPLARY EMBODIMENTS

Hereinafter, an embodiment of the present invention will be described. The embodiment does not limit the invention according to the claims, and all the combinations of the features described in the embodiment are not necessarily essential to means provided by aspects of the invention.

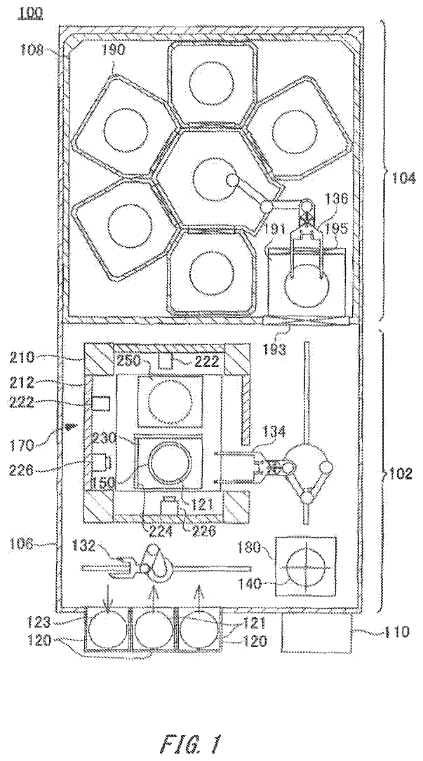

FIG. 1 is a schematic plane view of the substrate bonding apparatus 100. The substrate bonding apparatus 100 produces a multilayered substrate 123 by bonding a plurality of substrates 121.

Accordingly, the substrates 121 bonded in the substrate bonding apparatus 100 can be a semiconductor wafer such as a silicon single crystal wafer and a compound semiconductor wafer, as well as a glass substrate and the like. At least one of the bonded substrates 121 may also include a plurality of elements. Further, one or both of the bonded substrates 121 may be the multilayered substrate 123 which itself has been already manufactured by stacking wafers.

The substrate bonding apparatus 100 comprises an ordinary-temperature portion 102 and a high-temperature portion 104 formed inside a common cover 106. On the outer surface of the cover 106 in the ordinary-temperature portion 102, a total control section 110 and a plurality of FOUPs (Front Opening Unified Pod) 120 are disposed.

The total control section 110 controls the operation of each section of the substrate bonding apparatus 100 separately as well as controls the whole operation of the substrate bonding apparatus 100 comprehensively. The total control section 110 also includes an operating section operated by a user from the outside in inputting power activation, each setup, information, and the like of the substrate bonding apparatus 100, and a display section which transmits information to the user, and etc. Furthermore, the total control section 110 may include a connecting section that connects with other equipment additionally equipped for the substrate bonding apparatus 100.

The FOUP 120 accommodates the plurality of substrates 121 or the multilayered substrate 123. The FOUP 120 also can be separately attached and detached relative to the substrate bonding apparatus 100. This enables the plurality of substrates 121 bonded on the substrate bonding apparatus 100, to be accommodated into the FOUP 120, to be collectively loaded into the substrate bonding apparatus 100. The multilayered substrate 123 manufactured on the substrate bonding apparatus 100 is also accommodated into other FOUP 120 to be taken out of the substrate bonding apparatus 100 collectively.

Inside the cover 106 in the ordinary-temperature portion 102, loaders 132, 134, a pre-aligner 140, a stacking section 170, and a holder stocker 180 are disposed. The inside of the ordinary-temperature portion 102 is air-conditioned such that the almost same temperature as the normal temperature in the environment where the substrate bonding apparatus 100 is installed is maintained. As this stabilizes the operating precision of the stacking section 170, the positioning precision in stacking the substrates 121 is enhanced.

The loader 132 is disposed faced to the FOUP 120 and takes the bonded substrates 121 out of the FOUP 120. The substrates 121 taken out of the FOUP 120 are carried to the pre-aligner 140. In addition, in the depicted example, the pre-aligner 140 and the holder stocker 180 are vertically aligned.

The multilayered substrate 123 manufactured in the substrate bonding apparatus 100 is passed to the loader 132 from a loader 134 to be accommodated into the FOUP 120. In this manner, the loader 132 carries either the substrates 121 before bonding or the multilayered substrate 123 manufactured by bonding.

Incidentally, many of the substrates 121 bonded in the substrate bonding apparatus 100 is formed of thin and fragile materials. Because of this, the substrates 121 may be protected by causing a substrate holder 150 with higher strength and rigidity than the substrates 121 to hold the substrates 121 and by treating the substrates 121 and the substrate holder 150 integrally, within the substrate bonding apparatus 100.

The substrate holder 150 has a flat holding surface and has substrate holding functions such as an electrostatic chuck to attract the substrates 121 to the holding surface. The substrate holder 150 is picked up from the holder stocker 180 disposed in the ordinary-temperature portion 102 for use. The substrate holder 150 is also separated from the multilayered substrate 123 to be taken to return to the holder stocker 180. Therefore, the substrate holder 150 is repeatedly used within the substrate bonding apparatus 100.

The pre-aligner 140 aligns the substrate holder 150 and the substrate 121 together in causing the substrate holder 150 to hold the substrate 121. This fixes the loading position and loading direction of the substrate 121 to the substrate holder 150, relieving the burden of positioning work in the stacking section 170.

The loader 134 placed along the side of the stacking section 170 in the drawing picks up the substrate holder 150 from the holder stocker 180 to carry to the pre-aligner 140. The loader 134 also carries the substrate holder 150 that holds the substrate 121 in the pre-aligner 140 into the stacking section 170.

In addition, the holder stocker 180 accommodates a plurality of substrate holders 150. A function to cool down the substrate holder 150 taken out of the high-temperature portion 104 may also be provided in the holder stocker 180.

Furthermore, the loader 134 carries the substrates 121 stacked along with the substrate holder 150 in the stacking section 170, to the high-temperature portion 104. The loader 134 also carries the multilayered substrate 123 held between a pair of substrate holders 150, when taking the multilayered substrate 123 from the high-temperature portion 104. In this way, the loader 134 also carries a sheet or two of the substrate holders 150, in addition to the substrates 121 or the multilayered substrate 123. Therefore, for loader 134, the one with higher carrying capability than loader 132 is used.

The stacking section 170 has a fixed stage 250 and a fine motion stage 230 placed within a frame body 210. The fixed stage 250 is fixed to the frame body 210, and holds the substrate holder 150 and the substrates 121 downwardly. The fine motion stage 230 is loaded with the substrate holder 150 and the substrates 121, and relatively moves relative to the fixed stage 250 in the stacking section 170 to align a pair of substrates 121 and further stack it.

In the stacking section 170, the outer surface of the frame body 210 is closed by a wall member 212. This blocks the impact that radiant heat and the like from the circumference exerts to the stacking section 170.

The stacking section 170 also has an interferometer 222 and an image capturing section 226 placed within the wall member 212. The interferometer 222 utilizes a reflecting mirror 224 loaded on the fine motion stage 230 to accurately measure the position of the fine motion stage 230. The image capturing section 226 observes the surface of the substrates 121 loaded on the fine motion stage 230 to detect the surface quality. This enables the substrate 121 loaded on the fine motion stage 230 to be positioned accurately to the substrate 121 held in the fixed stage 250.

The high-temperature portion 104 is surrounded by a heat insulating wall 108 to maintain a high internal temperature as well as blocks thermal radiation to the outside. The high-temperature portion 104 comprises a loadlock 191, joining sections 190, and a loader 136.

The loadlock 191 has shutters 193, 195 alternately opening and closing, which prevent the high temperature atmosphere of the high-temperature portion 104 leaking into the ordinary-temperature portion 102. In the loadlock 191, the stacked substrates 121, along with substrate holder 150, are passed to the loader 136 from the loader 134 of the ordinary-temperature portion 102. The loader 136 carries the stacked substrates 121 into any of the joining sections 190.

The joining sections 190 pressurize the positioned substrate 121 to bond. By this, the substrates 121 become a multilayered substrate 123. In addition, the joining sections 190 may heat the substrates 121 in pressurization.

Again, the multilayered substrate 123 is taken from a joining section 190 by the loader 136 along with the substrate holder 150 and carried into the loadlock 191. The multilayered substrate 123 and the substrate holder 150 carried into the loadlock 191 from the high-temperature portion 104 are delivered to the loader 134 in the ordinary-temperature portion 102 in turn. The substrate holder 150 is also separated from the multilayered substrate 123.

In this manner, the loader 132 facing to the FOUP 120 accommodates the multilayered substrate 123 alone separated from the substrate holder 150 into the FOUP 120. The substrate holder 150 is also returned to the holder stocker 180 and reused in bonding other substrates 121.

Like this, in the substrate bonding apparatus 100, the joining sections 190 pressurize the substrates 121 positioned and stacked in the stacking section 170 for bonding. However, if the joined surface to be joined at each of the substrates 121 is clean and smooth, for example, the substrates 121 may be joined in the stacking section 170. In such a case, the high-temperature portion 104 including the joining sections 190 may be omitted.

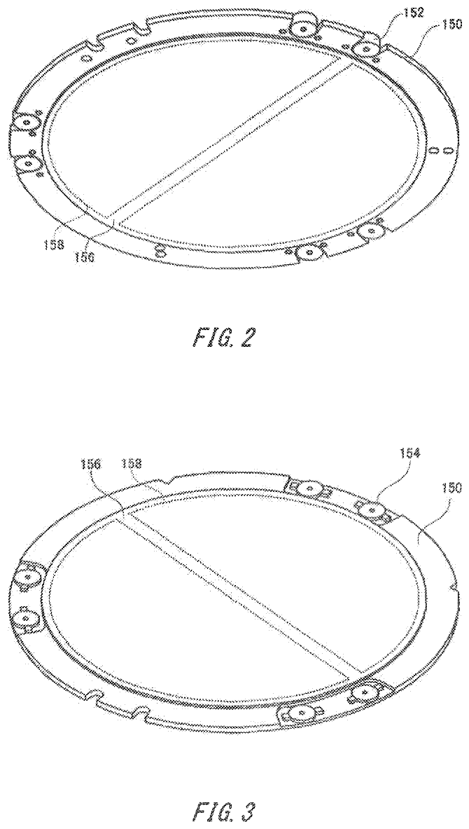

FIG. 2 is a perspective view showing the appearance of the substrate holder 150 inserted into the stacking section 170 downwardly, seen from the bottom. The substrate holder 150 is a discoid member having a circular placement surface 156 contacting the substrates 121 which it holds, and is formed of a hard material such as alumina ceramics. The substrate holder 150 also has an electrostatic chuck 158 that electrostatically attracts the substrates 121 to the placement surface 156 when voltage is applied to a buried electrode.

Further, the substrate holder 150 comprises a plurality of permanent magnets 152 placed along the side circumference. The permanent magnets 152, each, are fixed to the edge of the substrate holder 150 outside the placement surface 156.

FIG. 3 is a perspective view showing the appearance of the substrate holder 150 inserted into the stacking section 170 downwardly, seen from above. This substrate holder 150 also has the same shape and structure as the substrate holder 150 shown in FIG. 2, in that it has the placement surface 156 and the electrostatic chuck 158.

The substrate holder 150 has magnetic plates 154 instead of the permanent magnets 152. The magnetic plates 154 are placed in correspondence to the permanent magnets 152. Each of the magnetic plates 154 is also attached displaceably in the normal direction of the placement surface 156 and elastically to the substrate holder 150. This causes the permanent magnets 152 to attract the magnetic plates 154 to autonomously maintain the relative position of a pair of substrate holders 150 in the surface direction, if the substrate holder 150 shown in FIG. 2 and the substrate holder 150 shown in FIG. 3 are stacked to each other.

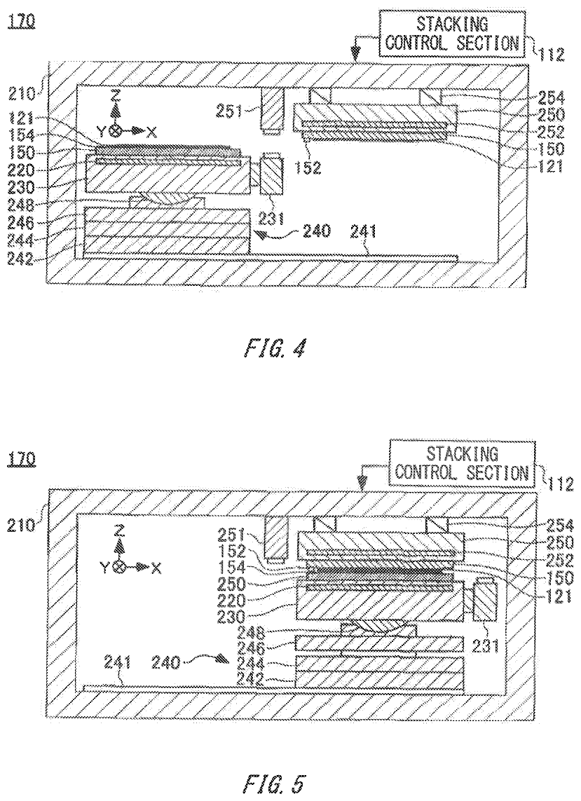

FIG. 4 is a schematic longitudinal sectional view of the stacking section 170. The stacking section 170 has a frame body 210, and a movable stage section 240 and a fixed stage 250 placed within the frame body.

The fixed stage 250 is suspended downwardly from the ceiling of the frame body 210 via a plurality of load cells 254. The fixed stage 250 comprises an electrostatic chuck 252. This causes the fixed stage 250 to attract the substrate holder 150 holding one of the substrates 121 provided for bonding, to the lower surface to hold.

In the depicted example, the substrate holder 150 equipped with the permanent magnets 152 as shown in FIG. 2 is held in the fixed stage 250. The plurality of load cells 254 separately measures the load applied to the fixed stage 250 from downward to above, to detect the load distribution in the surface direction of the substrate 121.

On the ceiling of the frame body 210, a downward microscope 251 is provided on the lateral side of the fixed stage 250. The microscope 251 has an automatic focusing function that focuses an optical system on the surface of the substrate 121 held on the fine motion stage 230, to observe the surface of the substrate 121. In addition, the relative position of the microscope 251 and the fixed stage 250 does not change, since the microscope 251 is fixed to the frame body 210.

The movable stage section 240 includes a movable surface plate 242, a coarse-motion stage 244, a gravity cancelling section 246, a spherical seat 248, and a fine motion stage 230. The movable surface plate 242 is loaded with the coarse-motion stage 244, the gravity cancelling section 246, and the fine motion stage 230, to move along a guide rail 241 fixed to the internal bottom surface of the frame body 210. The movement of the movable surface plate 242 causes the movable stage section 240 to move between the position directly under the fixed stage 250 and the position slightly away from that directly under the fixed stage 250.

The coarse-motion stage 244 moves relative to the movable surface plate 242 in the horizontal direction including an X direction component and a Y direction component as shown by arrow in the drawing. When relatively moving relative to the movable surface plate 242, the fine motion stage 230 also moves following the coarse-motion stage 244.

The gravity cancelling section 246 expands and contracts while detecting the fine displacement of the fine motion stage 230, to decrease the superficial weight of the fine motion stage 230. This relieves the load of an actuator displacing the fine motion stage 230 to enhance the precision in controlling the position.

The fine motion stage 230 has a holding section 220 to hold the substrate holder 150 holding the substrate 121 provided for bonding. In the positioning operation of the substrates 121, the fine motion stage 230 initially moves following the movement of the coarse-motion stage 244. In the next phase, the fine motion stage 230 is displaced relative to the coarse-motion stage 244. The displacement of the fine motion stage 230 relative to the coarse-motion stage 244 includes the translation and rotation relative to all of the X, Y, and Z axes.

The fine motion stage 230 also has a microscope 231 fixed on the lateral side. As the microscope 231 is fixed to the fine motion stage 230, the relative position of the fine motion stage 230 and the microscope 231 does not change. The microscope 231 has an automatic focusing function that focuses an optical system on the surface of the substrate 121, to observe the surface of the substrate 121 held in the fixed stage 250.

FIG. 5 is a schematic sectional view of the stacking section 170. The common elements with those in FIG. 4 are given the same numerical references to save repeated description.

In the depicted stacking section 170, the movable stage section 240 moves along the guide rail 241, and each of them is in the state of opposing to the fine motion stage 230 and the fixed stage 250 holding the substrate holder 150 and the substrate 121. Further, by positioning a pair of substrates which has been held, the fine motion stage 230 rises, and the pair of substrates 121 gets closer to each other.

If a pair of substrates 121 which are near to each other is closely stacked, pads on the substrates 121 are electrically coupled to each other via solder bumps and the like formed on at least one of the substrates 121. In this manner, elements on the pair of substrates 121 are coupled to each other to form a multilayered substrate 123. In other words, when the multilayered substrate 123 is formed, the positioning of the pair of substrates 121 is performed in the stacking section 170, such that the positions of pads, bumps, and the like correspond with each other.

However, the pair of substrates 121 is ultimately joined in the joining section 190. Therefore, the substrates 121 are fixed in a state positioned to each other in the stacking section 170. The fixed substrates 121 may be close to each other, or may be spaced from each other.

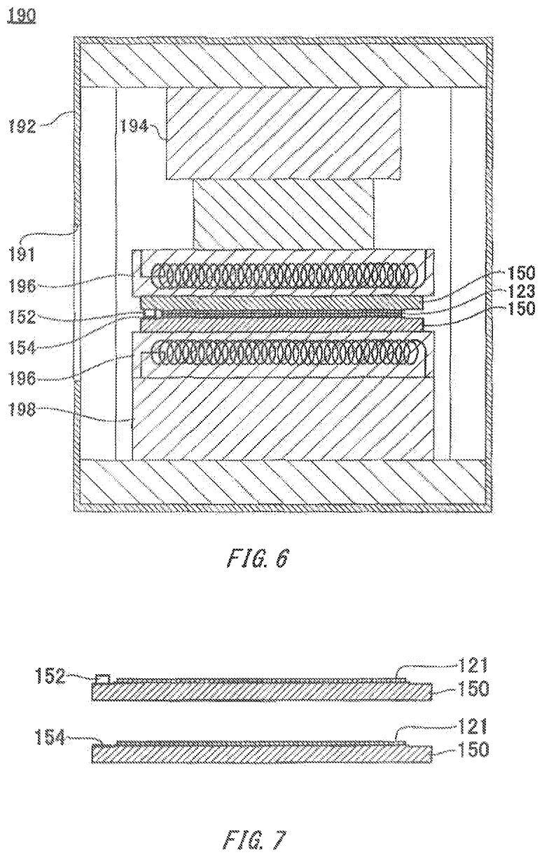

FIG. 6 is a schematic sectional view of the joining section 190. The joining section 190 has a surface plate 198 and a heat plate 196 alternately layered from the bottom of a housing 192, and a press-down section 194 and a heat plate 196 hung down from the ceiling of the housing 192. Each of the heat plates 196 incorporates a heater. On one of the sides of the housing 192, a carry-in entrance 199 is provided.

The substrates 121 which have already been positioned and stacked, and a pair of substrate holders 150 that hold the substrates 121 therebetween are carried together into the joining section 190. The substrate holders 150 and the substrates 121 which have been carried in are placed on the upper surface of the heat plate 196 of the surface plate 198.

The joining section 190 first raises the temperature of the heat plates 196, while descending the press-down section 194 to push down the upper heat plate 196. This causes the substrate holder 150 and substrates 121 held between the heat plates 196 to be heated and pressurized to be joined, and the substrates 121 become a multilayered substrate 123. The manufactured multilayered substrate 123 is taken from the joining section 190 by the loader 136.

In light of the application described above, the substrate holder 150 is required for the strength and heat resistance that it does not deteriorate although it repeatedly experiences heating and pressurization in the joining section 190. When the temperature of heating by the heat plate 196 is high, the surface of the substrates 121 may also react chemically with the atmosphere. Therefore, the inside of the housing 192 is preferably vented to generate a vacuum environment if the substrates 121 are heated and pressurized. Thus, a door which can be opened and closed to airtightly lock the carry-in entrance 199 may be provided.

Further, a cooling-down section may be provided in the joining section 190 to cool down the multilayered substrate 123 after heating and pressurizing. This enables to take the multilayered substrate 123 which has been cooled down to some extent, even if not reaching normal temperature, and to swiftly return it to the FOUP 120.

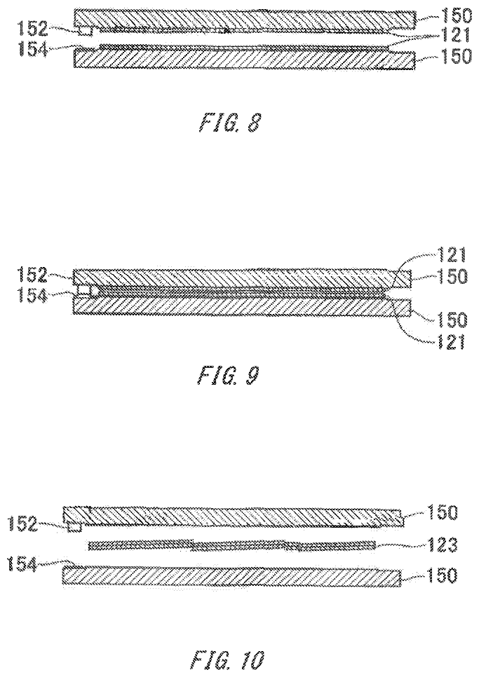

FIGS. 7, 8, 9, and 10 are drawings showing the changes in state of the substrates 121 in the substrate bonding apparatus 100. In reference to these drawings, the operation of the substrate bonding apparatus 100 will be described.

In the substrate bonding apparatus 100, the substrate holder 150 taken out of the holder stocker 180 by the loader 134 is first positioned on the pre-aligner 140 more accurately than a predetermined accuracy. Subsequently, the substrates 121 taken out of the FOUP 120 by the loader 132 one by one are loaded onto the substrate holder 150 in the pre-aligner 140 in a positioning accuracy over the accuracy predetermined for the substrate holder 150.

Thus, as shown in FIG. 7, the substrate holders 150 holding the substrates 121 are prepared. The substrate holders 150 loaded with substrates 121 are in turn carried to the stacking section 170 by the loader 134. This causes the substrates 121 and substrate holders 150 which initially have been carried, for example, to be rotated by the loader 134 and held in the fixed stage 250.

Then, the substrates 121 and the substrate holders 150 that have been carried in are held in the fine motion stage 230 in that orientation. In this way, as shown in FIG. 8, a pair of substrates 121, opposed to each other, is held in the stacking section 170.

Then, the pair of substrates 121 which have been positioned to each other is stacked by raising the fine motion stage 230, with the positioned state maintained. This allows the loader 134 to integrally carry the pair of substrates 121 and the substrate holders 150 positioned to each other, while maintaining the gap between the substrates 121.

In addition, the pair of substrates 121 has not yet been joined in this phase. Therefore, in this phase, fixing of the substrate holder 150 may be loosened to reposition the substrates 121 without damaging the substrates 121.

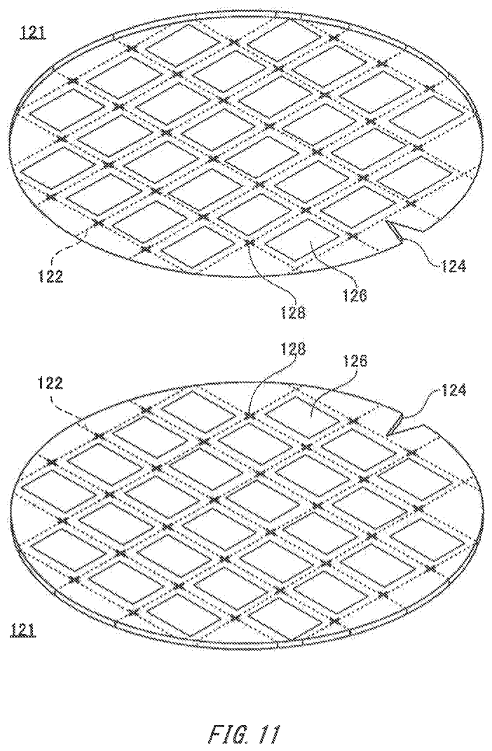

Subsequently, the loaders 134, 136 insert the substrate holders 150 holding the pair of substrates 121 into the joining section 190. The pair of substrates 121 heated and pressurized in the joining section 190 is perpetually bonded, and becomes the multilayered substrate 123 as shown in FIG. 10. Therefore, the loaders 134, 136 separate the substrate holders 150 and the multilayered substrate 123 to carry the substrate holders 150 to the holder stocker 180 and the multilayered substrate 123 to the FOUP 120, respectively. In this manner, a series of steps of manufacturing the multilayered substrate 123 is completed.

FIG. 11 is a conceptual perspective view of a pair of substrates 121 opposed to each other which are provided for joining. The substrates 121 have a discoid shape with a portion thereof chipped due to a notch 124, and respectively have a plurality of element regions 126 and alignment marks 128 on the surface.

The notch 124 is formed according to the crystal orientation and the like of the substrates 121. Therefore, the direction of the substrates 121 is determined with the notch 124 as an indicator when treating substrates 121.

On the substrates 121, the plurality of element regions 126 is periodically placed. In each of the element regions 126, a semiconductor apparatus is implemented which has been formed by processing the substrates 121 by means of photolithography technique and the like. A pad and the like which become a connection terminal when a substrate 121 is bonded to other substrate 121 are also included in each of the element regions 126.

In addition, between the element regions 126, there is a blank region in which functional elements such as elements, circuits and the like are not placed. In the blank region, scribe lines 122 are placed to cut off when cutting the substrates 121 into each of the element regions 126.

Further, on the scribe lines 122, the alignment marks 128 are placed that play the role of indicator when positioning the substrates 121. Since the scribe lines 122 disappears as a cutting margin in the process of cutting the substrates 121 to produce a die, the effective area of the substrates 121 is not disturbed by providing the alignment marks 128.

In addition, the element regions 126 and the alignment marks 128 are drawn in a large size in the drawing, but the number of the element regions 126 formed on the substrate 121 in the diameter of 300 mm, for example, may range to several hundred or more. A wiring pattern and the like formed on the element regions 126 may also be utilized as the alignment marks 128.

When positioning a pair of the substrates 121 to bond in the stacking section 170, a relative position of a substrate 121 is measured by observing the alignment marks 128 on an opposing substrate 121 with the microscopes 231, 251. Further, in order to resolve the displacement of the measured relative position, the substrates 121 can be positioned by moving the fine motion stage 230.

Different deformation in the thickness direction, however, may occur for each substrate, which may cause changes in an uneven state, due to differences in environmental conditions such as temperature in the photolithography process, even if it is a substrate 121 which has been made in the same exposure apparatus using the same mask. A foreign body sticking to the surface of the substrate 121 may also cause changes in the uneven state on a surface to be joined.

When a large change in the uneven state on the surface to be joined occurs on the substrate 121, a region in which the joined surface of one substrate 121 does not adhere to the joined surface of the other substrate may be produced, even though aligning by means of the alignment marks 128 arranged in the surface direction of the substrate 121 to be bonded, lowering the yield in the multilayered structure of the circuit on the substrate 121.

However, in the substrate bonding apparatus 100, the substrate 121 which has been determined to be unsuitable for bonding by pre-detecting the uneven state on the substrate 121 are eliminated without trying to bond. This can enhance the yield and throughput of the substrate bonding apparatus 100.

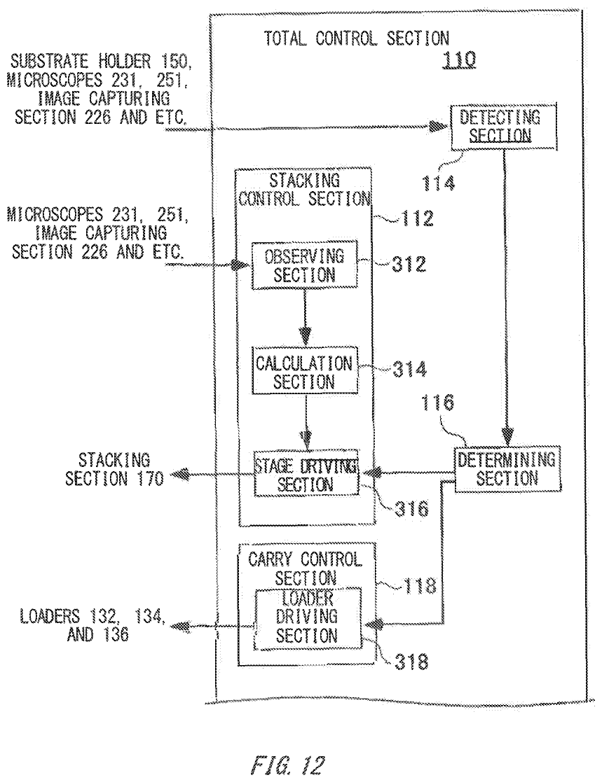

FIG. 12 is a block diagram showing a part of the total control section 110 in the substrate bonding apparatus 100. The total control section 110 has a stacking control section 112, a detecting section 114, a determining section 116, and a carry control section 118.

Detection of an uneven state by the detecting section 114 is performed before substrates 121 are joined in the joining section 190. Alternatively, the detection of the uneven state on the substrates 121 by the detecting section 114 may be performed before the substrates 121 are stacked in the stacking section 170. This enables to prevent the decrease in throughput and yield because of stacking the substrates 121 unsuitable for bonding due to an uneven state in advance.

The detecting section 114 detects an uneven state on the substrate 121 including an entire swell from an image in which the substrate 121 illuminated obliquely has been scanned by the image capturing section 226 disposed in the stacking section 170 and the like, for example. The detecting section 114 may also detect the uneven state on the substrate 121 from the operation of the automatic focusing mechanism of the microscopes 231, 251 provided in the stacking section 170. In addition, the disposition of the detecting section 114 is not limited to above, and it may be disposed at any location which can detect the uneven state on the substrate 121 before being carried into the stacking section 170. More specifically, the detecting section 114 may be disposed on a carry path leading from the FOUP 120 to the pre-aligner 140 or the stacking section 170, or it may be provided on a stage of the pre-aligner 140. At least one of the pre-aligner 140 and the stacking section 170 may also be used as part of the detecting section 114.

In this case, the detecting section 114 may detect the uneven state on the substrates 121 by detecting a protrusion on the joined surface of the substrates 121. That is, by measuring a region protruding above a predetermined threshold, e. g., 3 μm, relative to a reference surface assumed based on the holding surface of the substrate holder 150 holding the substrate 121 as a detected object and the thickness of the substrate 121, the uneven state on the substrates 121 can be detected. When the protrusion is observed for the purpose of detecting the uneven state on the substrate 121, the uneven state may be evaluated by measuring at least one of the height, area and area of the protrusion.

In addition, in the example described above, the image capturing section 226 is disposed in the stacking section 170, while the image capturing section 226 may be provided in other locations. The image capturing section 226 may also be disposed in other locations as well as within the stacking section 170.

When a detected protrusion is local to the entire area of the substrate 121, the detecting section 114 may also detect the protrusion as an adhered substance sticking to the substrate 121. In this way, the detecting section 114 may detect whether the material of the protrusion on the substrate 121, i. e., the protrusion is formed of the substrate 121 itself or of the adhered substance.

Furthermore, the detecting section 114 may detect the protruding direction of the protrusion on the substrate 121. This may enable to find out that the weight given to the substrates 121 by stacking, joining and the like of the substrates 121 may reduce or mitigate the detected protrusion to restrain the decrease in yield. Detecting the protruding direction of a protrusion also enables to select a method of efficiently pressing the protrusion in applying an external force in order to resolve the protrusion.

In addition, the detecting section 114 may detect an uneven state on a substrate 121 based on the load distribution measured by a load cells 254 in the stacking section 170. That is, if there is a large protrusion on the substrate 121, a large load occurs on the protrusion in stacking the substrates 121. Still, the detection of the uneven state based on the output of the load cells 254 may refer to the output of the load cells 254 during the work of stacking the substrates 121, or may refer to the output of the load cells 254 by pushing a sheet of substrate 121 against the fixed stage 250, simply for the purpose of detecting the uneven state.

The detecting section 114 may further obtain the information on the distance between the microscopes 231, 251 and the surface of the substrates 121 from an focusing mechanism which the microscopes 231, 251 have, to detect an uneven state. That is, the microscopes 231, 251 focus the optical system on a joined surface of the substrates 121 when observing the joined surface of the substrates 121. Therefore, the information on the distance to the joined surface of the substrates 121 or the information on the position of the joined surface can be obtained from the microscopes 231, 251, to detect the uneven state on the substrates 121.

The detecting section 114 may also detect an uneven state on the substrates 121 in the substrate holders 150. That is, when the substrates 121 have large unevenness, the contact area of the substrates 121 and the substrate holders 150 decreases. As this varies the current flowing on the surface of the substrates 121 attracted by the substrate holders 150, the uneven state on the substrates 121 can be electrically detected. More specifically, how many portions of uneven substrates 121 adhere to the flat substrate holders 150 can be detected, by measuring the impedance while applying alternating-current voltage to the electrostatic chuck of the substrate holders 150 attracting the substrates 121.

In addition, in the example described above, the case in which the substrate holders 150 use the electrostatic chuck to hold the substrates 121 is illustrated, while an uneven state on the substrates can also be detected in the substrate holders 150 having a vacuum chuck. If the substrate holder 150 comprises a vacuum chuck, the uneven state on the substrates 121 can be detected by measuring a negative pressure varying due to the atmosphere entering from the gap of the substrate holders 150 and substrates 121 according to the uneven state on the substrates 121.

Further, the detecting section 114 may detect an uneven state on the substrates 121 by referring to a pre-alignment operation in the pre-aligner 140. Since this enables to find out an uneven state before carrying the substrates 121 into the stacking section 170, measures for resolving or mitigating the uneven state can be taken in an early stage to enhance the throughput of the substrate bonding apparatus 100.

In the total control section 110, the stacking control section 112 includes an observing section 312, a calculation section 314, and a stage driving section 316. The observing section 312 detects the position of the alignment marks 128 for a pair of substrates 121 to be bonded, based on the image information obtained from the microscopes 231, 251 of the stacking section 170.

The calculation section 314 calculates the displacement of the pair of the substrates 121 from the position of the alignment marks 128 by statistically processing the position information of the alignment marks 128 detected by the observing section 312. This calculates the displacement of the relative position of the pair of substrates 121 carried into the stacking section 170 as a displacement amount.

The stage driving section 316 drives the fine motion stage 230 based on the displacement amount obtained from the calculation section 314, such that the displacement amount is denied. This positions the pair of substrates 121 to each other in the stacking section 170.

The determining section 116 determines whether the uneven state satisfies a predetermined condition based on the uneven state on the substrates 121 detected by the detecting section 114. In this embodiment, the determining section 116 determines whether to conduct bonding of the substrates 121 based on the uneven state on the substrates 121. That is, if the uneven state on a substrate 121 is extreme, the determining section 116 instructs the carry control section 118, without trying to stack or join, to return the substrate 121 to FOUP 120 without joining. This prevents stacking of the substrates 121 from requiring a lot of time and the throughput of the substrate bonding apparatus 100 from dropping.

Here, the determining section 116 may not only determine whether a substrate 121 may be bonded, but predict the yield of the product to eventually be acquired when the substrate 121 is bonded, and determine that the substrate 121 must not be bonded when the yield is expected to be worse than a predetermined threshold. The determining section 116 may also consider and determine whether the protrusion on the substrate 121 is to be mitigated or resolved for the attracting power of substrates 121 due to the substrate holders 150, the load applied to the substrates 121 because of stacking in the stacking section 170, and the load applied to the substrates 121 in joining in the joining section 190.

The carry control section 118 includes a loader driving section 318. The loader driving section 318 can drive three loaders 132, 134, and 136 to carry the substrates 121 and the substrate holders 150 and leave them to the processes at a carried destination. Therefore, the determining section 116 can generate instructions to the carry control section 118 according to determination results to select processes for the substrates 121.

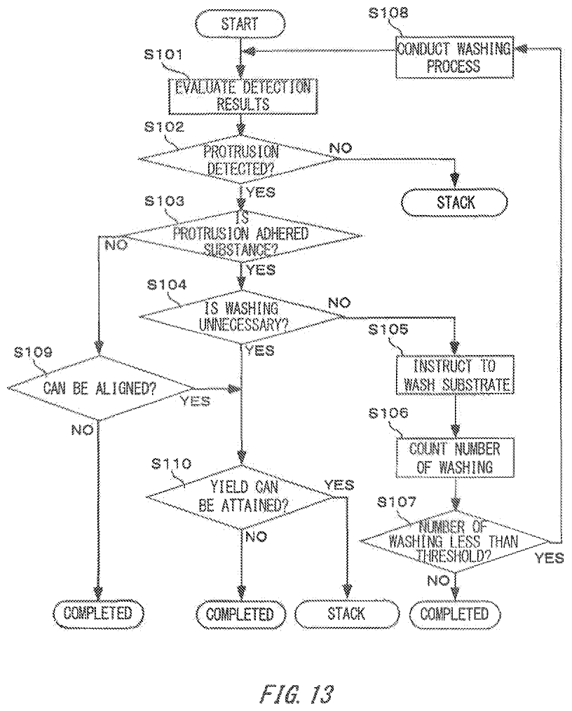

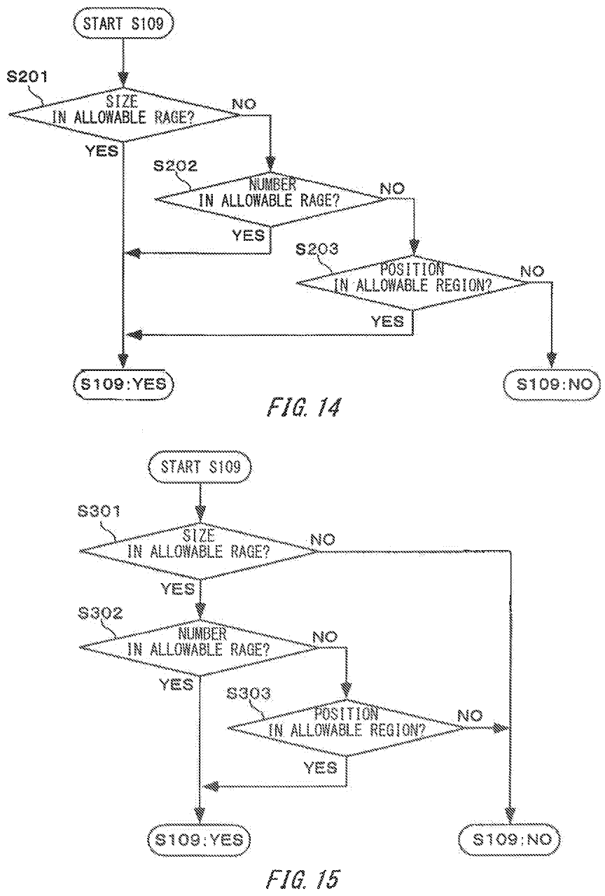

FIG. 13 is a flow chart showing the execution procedures of determining processes of the determining section 116 in the total control section 110. The determining section 116 first evaluates the detection results obtained from the detecting section 114 (Step S 101), and then examines whether there is a protrusion on the surface of a substrate 121 held between the substrate holders 150 (Step S 102).

In Step S 102, if no protrusion is detected on the surface of a substrate 121 (Step S 102: NO), then the determining section 116 determines that the surface of the substrate 121 is flat and smooth, to start to stack the substrate 121 in the substrate bonding apparatus 100. On the other hand, if a protrusion is detected on the surface of the substrate 121 in Step S 102 (Step S 102: YES), then the determining section 116 determines if the protrusion on the substrate 121 is formed of an adhered substance sticking to the substrate 121 (Step S 103: YES), or whether it is formed of the substrate 121 itself and the like (Step S 103: NO).

In Step S 103, if it is determined that the protrusion on the substrate 121 is not formed of an adhered substance (Step S 103: NO), then the determining section 116 determines that the detected uneven state originates from the deformation of the substrate itself, and determines whether the stacking section 170 can conduct aligning in that state (Step S 109).

In Step S 109, if the stacking section 170 determines that the aligning cannot be conducted (Step S 109: NO), then the processes for the substrate 121 is terminated. On the other hand, the determining section 116 proceeds to Step S 110 if it determines that the aligning for stacking can be conducted (Step S 109: YES).

In Step S 103, if it is determined that the protrusion on the substrate 121 is formed of an adhered substance (Step S 103: YES), the determining section 116 determines whether it is necessary to wash the substrate 121 to eliminate the adhered substance (Step S 104). In Step S 104, if it is determined that it is not necessary to wash the substrate 121 (Step S 104: YES), the determining section 116 proceeds to Step S 110 without washing the substrate 121.

In Step S 110, the yield in the multilayered substrate 123 is predicted. For example, the yield can be predicted as follows: First, based on the uneven state on a substrate 121 detected by the detecting section 114, substrates 121 that become a pair if the substrate 121 is bonded, and the position and area of the region which is not expected to adhere to each other are calculated. Then, the yield of the semiconductor apparatus to eventually be acquired can be predicted by counting the number of the elements included in the calculated region.

This causes the determining section 116 to execute a series of processes ranging from stacking to joining of substrates 121, when it is determined that the yield of the multilayered substrate 123 will reach a predetermined target value (Step S 110: YES). On the other hand, if it is determined that the yield will not reach the target value (Step S 110: NO), the determining section 116 terminates the processes for the substrate 121 without stacking and joining. The substrate 121 which has been determined to be unsuitable for bonding may be stored in one of the FOUPs 120 in order to destroy it, as described in Step S 107: NO below. In this way, by eliminating the substrate 121 for which it is predicted that the aligning in the stacking section 170 cannot be performed, prior to stacking, the drop in throughput of the substrate bonding apparatus 100 can be prevented.

In the Step S 110 above, it may be considered whether the uneven state on the substrate 121 will be improved by stacking to determine whether the yield reaches a predetermined target value. In this case, the determining section 116 determines, for example, whether the uneven state on the substrate 121 can be improved by the force of some N to several tens of N applied to the substrate 121, when stacking the substrate 121 in the stacking section 170. If the protrusion is not an adhered substance, it is determined whether at least one substrate 121 will be deformed by the force in stacking such that the unevenness produced on the substrate 121 comes close to flatness, or if at least one substrate 121 will be deformed such that the unevenness produced on at least one substrate 121 is complementary to the other substrate 121. On the other hand, if the protrusion is an adhered substance, it is determined whether the protruding amount of the adhered substance from the surface of the substrate 121 will be less than a predetermined value by the adhered substance being crushed by the force in stacking, based on the shape, size, materials and the like, as described below. When it is predicted that the uneven state on the substrate 121 will be improved by stacking, the determining section 116 determines whether the yield can be attained in the assumption that the uneven state is improved by stacking. In addition, by monitoring the noise occurring from making substrates 121, the distribution of the pressure applied to the substrates 121 and the like, the uneven state on the substrates 121 being improved may be verified when the substrates 121 are stacked.

The change in uneven state on the substrates 121 by stacking can also be predicted by the shape, height, number, location and the like of the protrusion detected from a substrate 121. If the shape of the protrusion is symmetrical or of a gradual slope, it is predicted that, by stacking, the protrusion is deformed by the weight applied to the substrate to come close to flatness. It is also expected that the uneven state will be improved by the weight applied by stacking when the height of the protrusion on the substrate 121 is low.

In the Step S 110 above, it may be considered whether the uneven state on the substrate 121 will be improved by joining in the joining section 190 to determine whether the yield will reach a predetermined target value. In this case, the determining section 116 determines whether the uneven state on the substrate 121 will be improved by the force of 10 t or more pressing down the substrate accompanied by joining by the joining section 190.

If it is predicted that the uneven state on the substrate 121 will be improved by joining, the determining section 116 determines whether the yield can be attained in the assumption that the uneven state can be improved by joining. The change in the uneven state on the substrate 121 by joining can be predicted based on the shape, height and the like of the protrusion on the substrate 121, similar to the change in the uneven state on the substrate 121 by stacking. When substrates 121 are joined, weight larger than stacking is applied to the substrates 121. If it is predicted that the uneven state on a substrate 121 can be improved by the stacking section 170 and the joining section 190, then it is also determined in the determining section 116 whether the time to be taken for the improvement will exceed a predetermined time, and if it is determined that it exceeds the predetermined time, a series of processes ranging from stacking to joining may be conducted without improvement.

In Step S 104, if it is determined that washing a substrate 121 is needed (Step S 104: NO), the determining section 116 instructs to wash the substrate 121 (Step S 105). The determining section 116 also counts how many times the substrate 121 has been washed for which the washing has been instructed (Step S 106). Further, the determining section 116 examines that the number of washing recorded for each of the substrates 121 has not reached a predetermined threshold (Step S 107).

When the number of the washing process for a substrate 121 has not yet reached the threshold (Step S 107: YES), the determining section 116 conducts the washing process for the substrate 121 to try to eliminate an adhered substance (Step S108). Further, after causing the detecting section 114 to detect the uneven state on the wash-processed substrate 121 again, the determining section 116 conducts the processes starting with evaluation of detection results (Step S 101) again. Therefore, the substrate 121 is repeatedly washed within the range of the threshold number above until the adhered substance is eliminated by washing.

Washing methods of substrates 121 may include a blow process that blows dry air or inert gas against the surface of a substrate 121 as well as the method of taking the substrate 121 out of the substrate bonding apparatus 100 to wash with washing liquid.

Further, the first washing may be the blow process, and the second washing and thereafter may be the washing with washing liquid, for example. Further, each time the washing is repeated, the type of washing liquids may be changed.

When the determining section 116 instructs to wash the substrate 121, the substrate 121 may be taken out of the substrate bonding apparatus 100 to put on the washing process. A plurality of substrates 121 to be washed may be stored in the FOUP 120 and the like to wash-process together later.

In Step S 107, if it is found out that the number of the washing process for the substrate 121 has already reached a threshold (Step S 107: NO), the determining section 116 determines that the possibility of eliminating an adhered substance to improve the state of the substrate 121, even if repeating to wash the substrate 121 further. Thus, the determining section 116 terminates the processes for the substrate 121.

The substrate 121 for which the processes by the determining section 116 is terminated may be stored in one of the FOUPs 120, for example. The detected uneven state may be recorded for each of the substrates 121 for which the processes have been terminated, and when a combination of the substrates 121 is produced which have an uneven state complimentary to each other, the substrates 121 may be combined to try to bond.

In addition, in the embodiment described above, a series of determination procedures above by means of the determining section 116 is executed to the substrates 121 held by the substrate holders 150. Alternatively, the detecting section 114 may also detect an uneven state on the substrates 121 in the stage before the substrates 121 are held on the substrate holders 150, and further predict the uneven state on the substrates 121 when the substrates 121 have been held by the substrate holders 150. This can eliminate the substrates 121 having an extremely large unevenness beforehand to prevent the attraction failure of the substrates 121 by the substrate holders 150 in advance. The prediction of the state where substrates 121 are held by the substrate holders 150 can accelerate focusing the microscopes in observing the surface of the substrates 121 held by the substrate holders 150 to enhance the processing speed of the detecting section 114.

In the series of determination procedures by the determining section 116 described above, large uneven state over the entire substrate 121 such as a curve of the substrate 121 may be included into the determination stuffs. Such a wide range of uneven state may be grasped by obtaining the information detected in a pre-step such as polishing process of the substrate 121, for example. Such an uneven state over the entire substrate 121 may also be determined by the determining section 116 in consideration of the improvement by stacking and joining.

Further, as stuff for predicting whether the uneven state on the substrate 121 can be improved, another substrate 121 may be contacted with the substrate 121 that is subject to bonding to detect the surface pressure distribution in the contacted state. Further, by sliding the substrate 121 in the contacted state, the surface quality may be detected via the friction of the substrate 121. Further, a collision noise that occurs when contacting the substrate 121, and a noise and the like produced when a force is applied to the substrate 121 to deform may be collected to detect the uneven state on the substrate 121 and the improvement of the uneven state.

FIG. 14 is a flow chart showing one example of the detailed control procedures of the determining section 116 in Steps S 104 and S 109 described above. In Step S 104 and S 109, the determining section 116 determines whether the size of a protrusion is within an allowable rage based on the information on an uneven state obtained from the detecting section 114 (Step S 201). The allowable range is set to a range in which an alignment mark on the protrusion comes into the depth of field in the automatic focusing function of the microscopes 231, 251, for example. As another example, the allowable range for size is set to the one where the residual in the global alignment falls in the threshold even if the alignment mark is out of a designed position due to the protrusion, for example.

The determining section 116 determines that the stacking section 170 can align a substrate 121 by comparing the predetermined threshold and the size of the protrusion, when the size of the protrusion on the substrate 121 is in the allowable range (Step S 109: YES).

The size of the protrusion, including the case of an adhered substance being formed, can be not only calculated based on an image acquired when observing the surface of the substrate 121 with the microscopes and the magnification of the microscopes, but also determined depending on whether the size of the protrusion exceeds the preset threshold founded on the depth of field, the automatic focusing range, and etc. of the microscopes.

In Step S 201, if the size of the protrusion is out of the allowable range, the determining section 116 examines from the information on the uneven state obtained from the detecting section 114 whether the number of protrusions is in an allowable range, for example (Step S 202). The allowable range for the number is set within the range in which the residual in the global alignment falls in a threshold even if the alignment mark is out of the designed position due to that number of protrusions.

The determining section 116 determines that the stacking section 170 can align the substrate 121 in spite of the determination in Step S 201, if the number of protrusions does not exceed the predetermined threshold (Step S 202: YES). The number of adhered substances on the substrate 121 can be calculated not only by the method of actually counting on an observed image, but also by the image processing to the observed image.

On the other hand, if it is found out in Step S 202 that the number of protrusions exceeds the threshold described above, the determining section 116 further examines from the information on the uneven state obtained from the detecting section 114 whether the position of a protrusion is located in an allowable region, for example (Step S 203). An example of the allowable region lies on the scribe lines 122.

If the position of the protrusion is located in the allowable region, it is determined that the stacking section 170 may align the substrate 121 despite the determination in Step S 202 above (Step S 109: YES).

However, if the position of the protrusion is located outside the allowable region in Step S 203, the determining section 116 determines that the stacking section 170 can no longer align the substrate 121 which has been subject to determination (Step S 109: NO). In this way, the determining section 116 may determine that aligning can be performed if the uneven state on the substrate 121 satisfies any one of the conditions.

The uneven state detected for each of substrates 121 which have been determined to be unsuitable for bonding may be recorded in association with the identification information such as a bar code provided for each substrate 121 to determine a set of bonding depending on the uneven state on the substrates 121. In this case, the substrates 121 to be bonded may combine the substrates 121 having an uneven state complementary to each other, and may combine the substrates 121 having protrusions and the like on a same position to each other, for example.

Further, if the substrates 121 have a bump, bump flatness may be improved by polishing process and the like, to try re-bonding. Further, the information on the substrates 121 which have been determined to be unbondable may be stored to reflect the improvement of the steps prior to being carried into the substrate bonding apparatus 100.

FIG. 15 is a flow chart showing another example of the detailed control procedures of the determining section 116 in the Steps S 104 and S 109 described above. Also here, the determining section 116 determines in Steps S 104 and S 109 whether the size of a protrusion is in an allowable range for the information on an uneven state obtained from the detecting section 114 (Step S 301).

The determining section 116 examines whether the size of the protrusion on a substrate 121 is in the allowable range. If the size of the protrusion on the substrate 121 is outside the allowable range, the determining section 116 immediately determines that the stacking section 170 cannot align the substrate 121 which have been subject to determination (Step S 109: NO).

On the other hand, if the size of the protrusion is in the allowable range (Step S 301: YES), the determining section 116 examines from the information on the uneven state obtained from the detecting section 114 whether the number of protrusions is in an allowable range (Step 302). Here, if the number of protrusions is in the allowable range (Step S 302: YES), the determining section 116 determines that the stacking section 170 can conduct aligning for the substrate 121 (Step S 109: YES).

However, if the number of protrusions is outside the allowable range in Step S303 (Step S 302: NO), the determining section 116 further examines from the information on the uneven state obtained from the detecting section 114 whether the position of the protrusion is included in an allowable region, for example (Step S 303). If the protrusion is located in the allowable region, the determining section 116 determines that the stacking section 170 can align the substrate 121 (Step S 109: YES).

However, if the position of the protrusion is located outside the allowable region in Step S 303, the determining section 116 determines that the stacking section 170 can no longer align the substrate 121 which have been subject to determination (Step S 109: NO). In this way, the determining section 116 may determine that aligning can be performed immediately for a part of the conditions, and still can be performed for other conditions by adding multiple conditions.

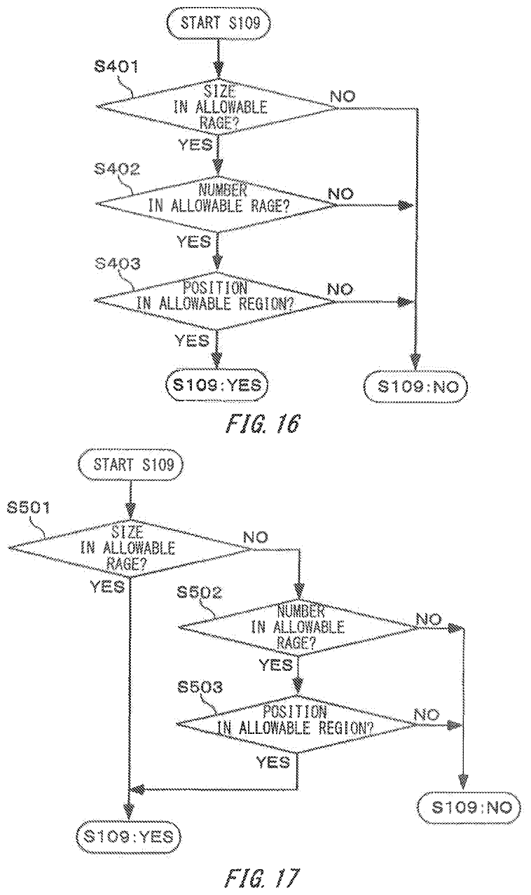

FIG. 16 is a flow chart showing still another example of the detailed control procedures of the determining section 116 in the Steps S 104 and S 109 described above. Also here, the determining section 116 determines in Steps S 104 and S 109 whether the size of a protrusion is in an allowable range for the information on an uneven state obtained from the detecting section 114 (Step S 401).

If the size of the protrusion on the substrate 121 is outside the allowable range (Step S 401: NO), the determining section 116 immediately determines that the stacking section 170 cannot align the substrate 121 which have been subject to determination (Step S 109: NO). On the other hand, if the size of the protrusion is in the allowable range (Step S 401: YES), the determining section 116 examines from the information on the uneven state obtained from the detecting section 114 whether the number of protrusions is in the allowable range (Step 402).

If the number of protrusions is outside the allowable range (Step S 402: NO), the determining section 116 determines that the stacking section 170 cannot align the substrate 121 (Step S 109: NO). If the number of protrusions is in the allowable range (Step S 401: YES), the determining section 116 examines from the information on the uneven state obtained from the detecting section 114 whether the position of the protrusion is in an allowable region (Step 403).

If the position of the protrusion is included in the allowable region, the determining section 116 determines that the stacking section 170 can align the substrate 121 (Step S 109: YES). However, if the position of the protrusion is outside the allowable region in Step S 403, the determining section 116 determines that the stacking section 170 cannot align the substrate 121 (Step S 109: NO). In this way, the determining section 116 may determine that aligning can be performed if any one of the conditions is outside an allowable range.

FIG. 17 is a flow chart showing still another example of the detailed control procedures of the determining section 116 in Steps S 104 and S 109. Also here, the determining section 116 determines in Steps S 104 and S 109 whether the size of a protrusion is in an allowable range for the information on an uneven state obtained from the detecting section 114 (Step S 501.

If the size of the protrusion on a substrate 121 is in the allowable range (Step S 501: YES), the determining section 116 immediately determines that the stacking section 170 can align the substrate 121 which have been subject to determination (Step S 109: YES). On the other hand, if the size of the protrusion is outside the allowable range (Step S 501: NO), the determining section 116 examines from the information on the uneven state obtained from the detecting section 114 whether the number of protrusions is in an allowable range (Step 502).

If the number of protrusions is in the allowable range (Step S 502: YES), the determining section 116 examines from the information on the uneven state obtained from the detecting section 114 whether the position of the protrusion is in an allowable region (Step 503). If the number of protrusions is outside the allowable range (Step S 502: NO), the determining section 116 also determines that the stacking section 170 cannot align the substrate 121 (Step S 109: NO).

If the position of the protrusion is included in an allowable region, the determining section 116 determines that the stacking section 170 can align the substrate 121 (Step S 109: YES). However, if the position of the protrusion is located outside the allowable region in Step S 503, the determining section 116 determines that the stacking section 170 cannot align the substrate 121 (Step S 109: NO). In this way, the determining section 116 may determine that substrate 121 can be aligned if any one of the conditions is in an allowable range.

In addition, the control procedures shown in FIGS. 14, 15, 16, and 17 are each simply an example, and the determining section 116 may determine in reference to more pieces of unevenness information. As such unevenness information, the determining section 116 may determine referring to other conditions than the size, number and position of protrusion, for example. The dispersion of height of bumps formed on a substrate 121, adhered substances sticking to a substrate 121, and the like may also be detected as unevenness information.

For example, if the detecting section 114 detects the flatness of bumps as unevenness information of a substrate 121, i. e., the dispersion of the height of bumps formed on the substrate 121 as unevenness information, the determining section 116 may determine whether to join the substrate 121 according to the bump flatness determined by the height of the top of bumps. In this case, the flatness of the substrate 121 does not come into question, and even if unevenness is produced on the substrate 121 due to ununiformed thickness of the substrate 121, the determining section 116 determines by means of the bump flatness. The bump flatness can be measured by using a confocal microscope, a three-dimensional shape measuring device and the like, for example.

When it is determined that the yield cannot be attained, based on the detected flatness of bumps (Step S 110: NO), when it is further determined that the yield cannot be improved by stacking, and when it is determined that the yield cannot be improved by joining, the determining section 116 generates an instruction to the carry control section 118 to eliminate the substrate 121 from the joining process.

The substrate 121 eliminated from the joining process may seek for other combinations that enhance the yield by joining in light of the flatness of the bumps on the detected substrate 121. The improvement of flatness of bumps by re-polishing and the like may also be tried. Further, the processing conditions of other substrates 121 such as bump formation, polishing and the like may be adjusted by abandoning to join the substrates 121 themselves eliminated from the joining process, and instead, by considering the flatness detected for the substrates 121. If the detecting section 114 detects an adhered substance sticking to the surface of the substrate 121 as unevenness information of the substrate 121 in Step S 103 above, then in Step S 110, the determining section 116 may predict the yield based on the material (composition), the size, and etc. of the adhered substance. The materials of an adhered substance can be estimated by observing the color, reflectivity, transmittance, shape and the like of the adhered substance under illumination by visible light or infrared light.

Detection of materials of an adhered substance also enables the determining section 116 to determine the solidity of the adhered substance (Young's modulus), whether there is generation of outgas or not, and the like. Further, estimation of physical properties of an adhered substance enables to predict the drop in yield of an multilayer type semiconductor apparatus which originates from the adhered substance produced in joining the substrate 121, with the adhered substance left thereon.

That is, when it is predicted that the materials of an adhered substance has a high Young's modulus and will not be squashed by pressurization through joining, for example, the drop in yield due to the adhered substance gets larger. Also, even if the Young's modulus of the adhered substance is low and is easily deformed by pressurization through joining, the drop in yield due to the adhered substance cannot be ignored, when the size of the adhered substance is big. Furthermore, even though joining can be performed by pressurization through joining, the yield is affected by the adhered substance when outgas is generated from the adhered substance, as that may chemically transmute the substrate 121.

In addition, adhered substances which may stick to substrates 121 in the substrate bonding apparatus 100 may include ceramic materials such as SiC, stainless materials such as SUS 304, aluminum-like metals such as YH 75, fine resin particles represented by heat-resistant resins such as PEEK (polyetheretherketone). Table 1 below illustrates these physical properties.

TABLE 1

| | Young′s modulus | allowable particle |
|---|---|---|
| Materials | (GPa) | size (μm) |
| SiC | 410.0 | 3.0 |
| SUS304 | 193.2 | 3.0 |
| YH75 | 72.0 | 5.0 |
| PEEK | 7.3 | 10.0 |

As described above, the materials of the adhered substances which may stick to the substrates 121 in the substrate bonding apparatus 100 respectively have specific physical characteristics. Therefore, depending on the compositions of detected adhered substances, the impact given to joining yield of the substrates 121 can be estimated.

In addition, an allowable particle size means the particle size of an adhered substance where the yield of a finished product is presumed to fall in an allowable range, if the substrates 121 are joined with the adhered substance left thereon. Therefore, if joining conditions for heating the substrates 121, for example, are set, the allowable particle size may be altered by joining temperature.

If there is no expectation of attaining the yield based on the compositions, size and the like of the adhered substances which have been detected (Step S 110: NO), if there is further no expectation of improving the yield by stacking, and if there is no expectation of improving the yield by joining, the substrates are eliminated from the joining process. To the eliminated substrates, joining may be tried again after processes such as washing. The cause for generating an adhered substance may also be presumed to conduct cleaning and maintenance of the substrate bonding apparatus 100 according to detected adhered substances.

In the examples described above, the case is described in which the determining section 116 determines whether the stacking section 170 can align the substrates 121 (Step S 109). However, the control procedures as described above may also apply to the case where the determining section 116 determines the yield of the multilayered substrate 123 manufactured by bonding the substrates 121 in the substrate bonding apparatus 100 (Step S 110).

In addition, while the examples described above describe the processes by the determining section 116 to one sheet of substrate 121 in turn, however, in the substrate bonding apparatus 100, more than 3 sheets of substrates 121 are processed in parallel. Therefore, the processes in the determining section 116 are also conducted to a plurality of substrates 121 in parallel.

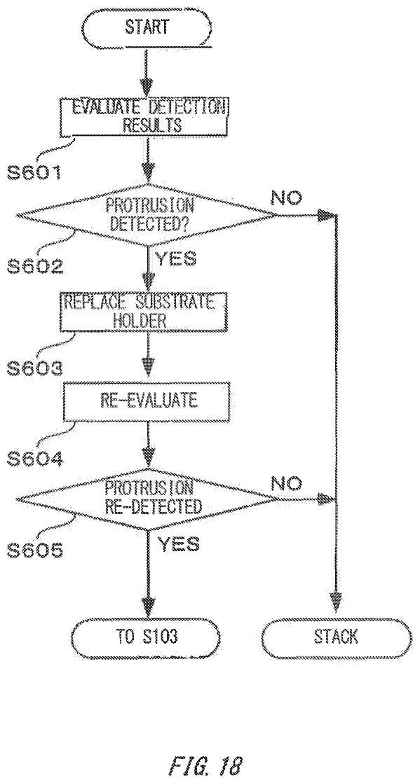

FIG. 18 is a flow chart showing other execution procedures of the determine process of the determining section 116 in the total control section 110. In these execution procedures, the determining section 116 first evaluates detection results obtained from the detecting section 114 (Step S 601) to examine whether a protrusion can be detected on the surface of substrates 121 held by the substrate holders 150 (Step S 602).

In Step S 602, the determining section 116 determines whether there is a protrusion on the surface of a substrate 121 based on the size, number, position and the like of the protrusion, similar to the procedures of Step S 102 shown in FIG. 13. If no protrusion is detected in Step S 602 (Step S 602: NO), the determining section 116 determines that the surface of the substrate 121 is flat and smooth to start to stack the substrate 121 in the substrate bonding apparatus 100.

If a protrusion is detected on the surface of the substrate 121 in Step S 602 (Step S 602: YES), the determining section 116 causes a substrate holder 150 holding the substrate 121 to be replaced for another substrate holder 150 (Step S 603). Further, the determining section 116 re-evaluates the substrate 121 held by the other substrate holder 150 (Step S 604) to re-detect a protrusion (Step S 605).

If no protrusion is detected on the surface of a substrate 121 held by the other substrate holder 150 in Step S 605 (Step S 605: NO), the protrusion of the substrate 121 which is at the detection threshold or less is estimated to have originated from the surface characteristics of the substrate holder 150 before being replaced. Therefore, the determining section 116 starts to stack the flattened substrate 121 by the substrate bonding apparatus 100. In addition, the surface characteristics of the substrate holder 150 include an undulation produced if an adhered substance sticks to the attracting surface of the substrate holder 150, in addition to the flatness of the attracting surface of the substrate holder 150.

If a protrusion is detected on the surface of the substrate 121 in Step S 605 (Step S 605: YES), the cause for generation of a protrusion is determined to lie in the substrate 121 itself such as ununiformed thickness of the substrate 121 and the like, as the replacement of the substrate holder 150 does not get the protrusion on the substrate 121 to be at or less than the detection threshold. Therefore, the determining section 116 executes the procedures in Step S 103 and thereafter, of the procedures shown in FIG. 13, for the substrates 121 held by the substrate holders 150.

That is, the determining section 116 first determines whether the protrusion on the substrate 121 is formed of an adhered substance sticking to the substrate 121 (Step S 103: YES) or whether it is formed by deformation of the substrate 121 itself (Step S 103: NO). If it is determined that the protrusion on the substrate 121 is formed of the adhered substance (Step S 103: YES), the determining section 116 determines whether washing is necessary (Step S 104), and when washing is not needed (Step S 104: YES), the substrate 121 is aligned and bonded with the adhered substance left thereon.

If it is determined in Step S 104 that washing is necessary for a substrate 121 (Step S 104: NO), the determining section 116 conducts the washing process (Step S 108) after instructing to wash the substrate 121 (Step S 105), after counting the number of washing (Step S 106), and after examining that the number of washing has not reached a given threshold (Step S 107). If the number of washing has already exceeded the given threshold (Step S 107: NO), the process for the substrate 121 is terminated.

If it is determined in Step S 103 that the protrusion on the substrate 121 is not an adhered substance (Step S 103: NO), the determining section 116 determines whether the stacking section 170 can complete aligning in that state (Step S 109). If it is determined here that aligning cannot be completed (Step S 109: NO), the determining section 116 terminates the process for the substrate 121.

If it is determined in Step S 109 that aligning can be performed (Step S 109: YES), the determining section 116 predicts a yield of the semiconductor type apparatus and the like acquired from the multilayered substrate 123 when conducting stacking and joining subsequent to aligning (Step S 110). If it is predicted in this prediction that the yield can be attained, the determining section 116 starts to stack the substrate 121 (Step S 110: YES).

If it is determined that the yield cannot be attained in that way (Step S 110: NO), the determining section 116 may also predict whether the yield can be attained by an artifice in stacking the substrate. If it is predicted in this prediction that the yield can be attained, the determining section 116 may change the determination for the substrate 121 to determine that the yield is attainable, and start to stack the substrates 121 (Step S 110: YES).

If it is further determined that the yield cannot be attained in the stage above, the determining section 116 may predict whether the yield can be attained by the pressurization in the stage of stacking the substrate. If it is predicted in this prediction that the yield can be attained, the determining section 116 changes the determination for the substrates 121 to determine that the yield is attainable, and start to stack the substrate 121 (Step S 110: YES).

In this way, in the embodiment described above, the protrusion on the substrate 121 originating from the characteristics of the substrate holder 150 is clearly distinguished to enable to prevent the drop in yield of the substrates 121 due to generation of protrusion. Even if it is determined that there is a protrusion on the substrate 121 itself, the drop in yield of the substrates 121 can be restrained by trying various determinations for the substrates 121. It has been already described that the substrates 121 which have been determined to be unsuitable for bonding are eliminated from the bonding line in the case of Step S 109: NO and Step S 107: NO.

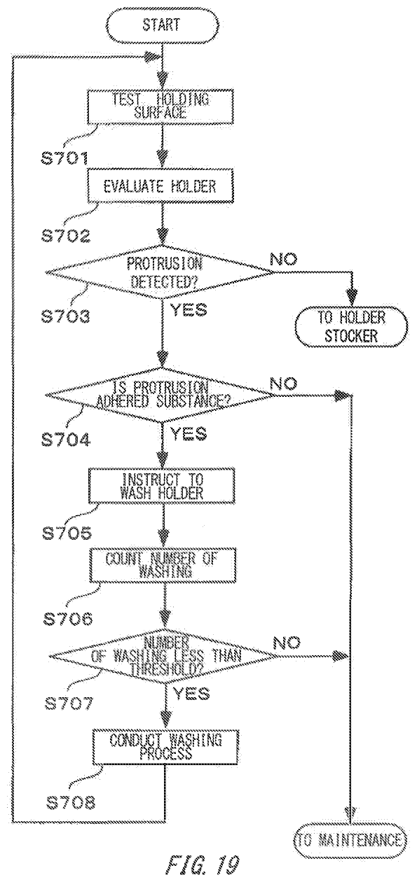

FIG. 19 is a flow chart showing one example of handling procedures of the substrate holder 150 removed from a substrate 121 for replacement in Step S 603. The substrate holder removed from the substrate 121 is first tested by the detecting section 114 for a protrusion on the holding surface to hold the substrate 121.

Subsequently, the determining section 116 evaluates the detection results by the detecting section 114, similar to the surface of the substrate 121 (Step S 702). This causes the determining section 116 to detect whether there is a protrusion on the holding surface of the substrate holder 150 (Step S 703). If no protrusion is detected on a holding surface in Step S 703 (Step S 703: NO), the substrate holder 150 is regarded as having a flat holding surface and returned to the holder stocker 180 in the substrate bonding apparatus 100. The returned substrate holder 150 is again used to bond substrates 121. The substrate holder 150 may be carried to the pre-aligner 140 without returning to the holder stocker 180.

If a protrusion is detected on a holding surface in Step S 703 (Step S 703: YES), the determining section 116 subsequently examines whether the detected protrusion is due to an adhered substance (Step S 704). If it is found out that the protrusion on a substrate holder is not due to the adhered substance (Step S 704: NO), the determining section 116 determines that the protrusion originates from the deformation of the substrate holder 150 itself, and causes the substrate holder 150 to be taken out of the substrate bonding apparatus 100 for the purpose of maintenance.

If it is found out in Step S 704 that a protrusion on a substrate holder 150 is formed of an adhered substance (Step S 704: YES), the determining section 116 generates an instruction to wash the substrate holder 150 (Step S 705). Here, the determining section 116 counts the number of conducting the washing process for the substrate holder 150 (Step S 706), and examines that the counted number of washing has not exceeded a predetermined threshold (Step S 707).

In Step S 707, if the number of washing for the substrate holder 150 has reached the threshold above (Step S 707: NO), the determining section 116 determines that the adhered substance on the substrate holder 150 cannot be eliminated by washing, and causes the substrate holder 150 to be taken out of the substrate bonding apparatus 100 for the purpose of maintenance.

In Step S 707, if the number of washing for the substrate holder 150 has not reached the threshold above (Step S 707: YES), the determining section 116 conducts the washing process for the substrate holder 150 (Step S 708), and conducts a series of processes starting with the evaluation of the adhesion surface again after washing (Step S 710). This causes the substrate holder 150 to be returned to the holder stocker 180 in the substrate bonding apparatus 100 to be reused for bonding substrates 121, if the adhered substance is eliminated by the washing process.

In this way, in the embodiment described above, the cause of the protrusion formed on the substrate 121 is classified into the case in which the cause lies in the substrate holder 150 and the case in which it lies in substrates 121. If the cause lies in the substrate holder 150, the protrusion on the substrate 121 is promptly resolved by replacing the substrate holder 150. If the cause of the protrusion on the substrate 121 lies in the substrate 121 itself, conditions for conducting bonding is sought for in the presence of the protrusion, to restrain the drop in yield in the substrate bonding apparatus 100.

In addition, the evaluation of the substrate holder 150 and washing by blow process and the like can be conducted by using a pre-aligner 140 in the substrate bonding apparatus 100, for example. The substrate holder 150 removed from the line due to replacement may also be stored in the substrate bonding apparatus 100 to be maintained by a batch process outside the substrate bonding apparatus 100. In the maintenance, the holding surface of the substrate holder 150 is polished, for example, to flatten the holding surface.

While the embodiment of the present invention has been described, the technical scope of the invention is not limited to the above described embodiment. It is apparent to persons skilled in the art that various alterations and improvements can be added to the above-described embodiment. It is also apparent from the scope of the claims that the embodiments added with such alterations or improvements can be included in the technical scope of the invention.

It should be noted that the order of execution in each process such as operations, procedures, steps and stages and the like in apparatuses, systems, programs, and methods shown in the scope of claims, specification, and drawings are not specifically exhibited as “more previously”, “prior to”, and the like, and may be realized in any order, unless an output in a previous process is otherwise used in a later process. While the phrases such as “first”, “subsequently”, and the like are used for convenience to describe operation flows in the scope of claims, specification, and drawings, that does not mean that it is essential to embody in this order.

As it is apparent from the description above, a substrate bonding apparatus and a substrate bonding method may be realized according to the embodiments of the present invention.

1-48. (canceled)

49. A substrate joining method to join a first substrate and a second substrate together, comprising:
detecting, using information from a pre-joining step or an electrical detection method, an uneven state of a first substrate and a second substrate;
based on the uneven state detected by the detecting step, determining whether the first substrate and the second substrate are to be joined; and
joining the first substrate and the second substrate together aligned to each other when determining that the first substrate and the second substrate are to be joined, and preventing the joining when determining that the first substrate and the second substrate are not to be joined.

50. The substrate joining method to join the first substrate and the second substrate together according to claim 49, wherein the uneven state includes
information regarding at least one of a dispersion of height of a bump on the joining surface of the first substrate,
ununiformed thickness of the first substrate, and
an adhered substance sticking to the joining surface of the first substrate.

51. The substrate joining method to join the first substrate and the second substrate together according to claim 49, further comprising
holding the first substrate with a holding member,
preventing the joining of the first substrate and the second substrate together based on the uneven state while in a held state by the holding member, and
applying an AC voltage to the first substrate through the holding member.

52. The substrate joining method to join the first substrate and the second substrate together according to claim 49, further comprising
detecting the uneven state of at least one of the joining surface of the first substrate and the joining surface of the second substrate.

53. The substrate joining method to join the first substrate and the second substrate together according to claim 52, wherein
the uneven state is further detected based on a distribution of weight applied to the first substrate and the second substrate when the first substrate and the second substrate are stacked together.

54. The substrate joining method to join the first substrate and the second substrate together according to claim 49, wherein
the uneven state includes information regarding dispersion of a height of bumps on one of the joining surface of the first substrate and the joining surface of the second substrate.

55. The substrate joining method to join the first substrate and the second substrate together according to claim 49, wherein
the pre-joining step is a polishing process.

56. The substrate joining method to join the first substrate and the second substrate together according to claim 49, wherein the electrical detection method comprises:
measuring an impedance while applying an AC voltage to an electrostatic chuck of a substrate holder attracting at least one of the first substrate and the second substrate.

57. A substrate joining method to join a first substrate and a second substrate together, comprising:
detecting an uneven state of a first substrate and a second substrate;
determining based on the uneven state, at least one of:
at least one of a size and a position of an adhesive region or a non-adhesive region in joining the first substrate and the second substrate;
a number of element regions included in at least one of the adhesive region or the non-adhesive region; and
a yield in joining the first substrate and the second substrate;
based on a determination result of the determining step, determining whether the first substrate and the second substrate are to be joined; and
joining the first substrate and the second substrate together aligned to each other when determining that the first substrate and the second substrate are to be joined, and preventing the joining when determining that the first substrate and the second substrate are not to be joined.
